(19) United States
(12) Patent Application Publication
(10) Pub. No.: US 2002/0168806 A1
(43) Pub. Date: Nov. 14, 2002

(54) Automated processing method and system for product wafer and non product wafer, and recording medium in which the method is recorded

(75) Inventor: Koji Tokuyama, Tokyo (JP)

Correspondence Address: LAFF, WHITESEL, CONTE & SARET, 401 North Michigan Avenue, Chicago, IL, 60611, US

(73) Assignee: NEC Corporation

(21) Appl. No.: 09/734,958

(22) Filed: Dec. 11, 2000

(30) Foreign Application Priority Data
Dec. 14, 1999 (JP) 11-354979

(51) Int. Cl. H01L 21/00; H01L 21/84

(52) U.S. Cl. 438/151; 438/152

(57) ABSTRACT

Carrying control and information management in accordance with individual groups are executed without human operators. A host computer receives a load request from a process equipment and is triggered by the request to dispatch a product lot comprising a non product wafer stored on a storage shelf to the equipment which made the request, and to send a command to carry the lot to an AMHS. Some processing equipment execute processing while holding a dummy wafer, and some equipment require a wafer for insitu cleaning at specified frequency. By setting an application group as information in the load request from the processing equipment, the non product wafer required by the processing equipment can be carried at the required timing. Moreover, a non product wafer which was processed for the purpose of guaranteeing the product can be determined from its flow and application group, enabling processing information of the non product wafer to be linked to the history of the product lot.

### BACKGROUND OF THE INVENTION

1. Field of the Invention

The present invention relates to a method and system for automatically processing a non product wafer, used in guaranteeing the quality of a semiconductor product and controlling various process equipment, and a recording medium which programs for executing the method are recorded in.

2. Description of the Related Art

In a semiconductor production line, in addition to product semiconductors, non product wafers (hereinafter termed “NPW”) as passed along the line for the purposes of guaranteeing the quality of the product wafer and controlling various types of process equipment, such as a diffusion furnace and a sputtering equipment. Most NPWs operate locally near the processing equipment and are cut-off completely from the production system. Timings and other controls during operation are all dependent on the human operator.

As shown in Table 1, some NPWs follow the same process flow on the production system as the product. In a line where the product is not automated, the NPWs have a process flow indistinguishable from the product, but in a line where the product is automated, means for identifying the NPWs are provided in the production system in order to distinguish the NPWs from the products. In a line where the product is automated, a load request from a process equipment triggers the host computer to dispatch only products on an in-process shelf to the process equipment which made the request, and the host computer generates a command to carry the product.

TABLE 1

| NPW NAME A: NPW | | PRODUCT NAME B: PRODUCT | |
|---|---|---|---|
| PROCESS 1 | RECIPE 1 | PROCESS 1 | RECIPE 1 |
| PROCESS 2 | RECIPE 2 | PROCESS 2 | RECIPE 2 |
| PROCESS 3 | RECIPE 3 | PROCESS 3 | RECIPE 3 |
| PROCESS 4 | RECIPE 4 | PROCESS 4 | RECIPE 4 |
| PROCESS 5 | RECIPE 5 | PROCESS 5 | RECIPE 5 |
| PROCESS 6 | RECIPE 6 | PROCESS 6 | RECIPE 6 |

On the other hand, the carrying timing of the NPW is determined by a human operator, and a carrying command for the NPW is issued via the host computer. To control the status of the processing equipment, information is managed in broad classifications of “in-operation” during processing of the product and “preparatory operations” during processing of the NPWs. Histories of the product and the NPW are kept independently.

As described above, in the conventional semiconductor production line, a human operator controls the timings according to which the NPWs are carried to the process equipment. This is not desirable, since human operators must be incorporated into the line, consequently creating a source of particle generation for the product. Since the NPWs are managed by a human operator, there is a high potential for human error such as missed checks.

Further, even though the NPW is necessary to pass the product along the line, the NPW and product histories are maintained independently during information management. As a consequence, the relationship of the NPW to the product is not easy to track, placing a burden on the operator who manages the histories. Therefore, when automation is realized after collecting the NPWs as a single category, they can only be controlled according to a single pattern. When sending a load request to the host computer, the process equipment is subject to a single condition that it is in a status where carrying is possible. For this reason, it has not been possible to achieve a flexible and expandable method of controlling carrying and tracking.

### SUMMARY OF THE INVENTION

The present invention has been realized in consideration of the circumstances described above. It is an object of this invention provide a method and system for automatically processing a non product wafer which can provide application information relating to the NPW in a master file which determines the process flow and processing conditions of the NPW, and control carrying and manage information in accordance with individual applications, and also to provide a recording medium which the method is recorded in as a program.

It is another object of this invention to provide a method and system for automatically processing a non product wafer wherein, by appending application information to a load request from the processing equipment, it is possible to automatically carry the NPW of the required application at a timing which can be determined only by the processing equipment, and also to provide a recording medium which the method is recorded in as a program.

In order to achieve the above objects, a first aspect of this invention provides a method for automating product wafers and non product wafer in an automated semiconductor production system, in which one or more process equipment relating to semiconductor production are controlled by a host computer, and carrying and process tracking of product wafers including non product wafers are automated. The method comprises the steps of appending application groups, which are classified according to purpose and operation in the respective processes, by a host computer as information in a master file which the flow of the processes and conditions for processing in each of the processes are stored; and providing processing conditions comprising application groups which are stored in a master file in accordance with load requests for the product wafer and non product wafer generated by the equipment, whereby the product wafer and non product wafer can be carried in accordance with their individual application groups and process tracking can be controlled.

Consequently, the applications of the NPWs are classified in detail with regard to carrying control, process tracking, and information management, and the classifications are held in the master file for each process of the NPW process flow. By consulting the master file, it is possible to automate the operations of tracking the processes and carrying the NPWs which are required as the product lots pass along the line. The line can be completely automated without the need for human operators.

According to a second aspect of the automated processing method for non product wafer, in the method of the first aspect, the host computer determines a non product wafer to be processed by the process based on the process flow and application group, and correlates the processing history of the product lot with the processing history of the non product wafer, based on one of the equipment type, lot number, processing conditions, and process, at least.

Consequently, the host computer can identify non product wafers which were processed for the purpose of guaranteeing the product based on the application groups, and can link processing information of the non product wafers to the histories of the product lots. Therefore, the difficulty of tracking the product history at a later date can be reduced.

According to a third aspect of the automated processing method for non product wafer, in the first aspect, the host computer determines the purpose of each type of product lot and non product lot based on application groups contained in inquiry responses from the process equipment, and updates the status of the equipment. Consequently, in controlling the equipment status, the purpose of the processed non product wafer can be determined from its application group and the equipment status can be displayed, increasing the precision of the equipment operating information.

According to a fourth aspect of the automated processing method for non product wafer, in the first aspect, with regard to a non product wafer which requires regular processing, the host computer individually controls at least one of (i) the time elapsed since the previous check and (ii) the number of lots processed in accordance with processing conditions, and issues a carrying command for the non product wafer after counting a predetermined time or a predetermined number of processed lots.

Consequently, the host computer can manage the frequency of a non product wafer which requires regular processing, and can send a carrying command for the non product wafer which is stored on the in-process shelf at the required timing, enabling the non product wafer to be carried at the required timing without waiting for a human operator. This reduces waster time and increases reliability.

According to a fifth aspect of the automated processing method for non product wafer, in the first aspect, the process equipment supplies and withdraws non product wafers in accordance with application groups obtained from inquiry responses to the host computer, or combinations of batched application groups.

Some processing equipment execute processing while holding a dummy wafer at all times, and some equipment require a wafer for insitu cleaning at specified frequency. By setting application groups as information in the load request from the processing equipment, the NPWs required by the processing equipment can be carried at the required timing.

A sixth aspect of the invention provides a semiconductor production automating system for automating the carrying and process-tracking of product wafers including non product wafers, one or more process equipment being controlled by a host computer. The system comprises a storage shelf which stores the product wafers comprising non product wafers in lot units; and an automatic vehicle which carries the product wafers comprising non product wafers to and from the storage shelf and the process equipment in compliance with carrying commands issued by the host computer. The host computer appends application groups, which are classified according to purpose and operation in the respective processes, as information in a master file which the flow of the processes and conditions for processing in each of the processes are stored, and provides processing conditions comprising application groups which are stored in the master file in accordance with load requests for the product wafers and non product wafers generated by the equipment.

According to this constitution, the host computer receives a load request from the process equipment and, triggered by this request, dispatches a lot held on a in-process shelf to the equipment and sends a command to carry the lot to an automated vehicle. Furthermore, some process equipment, for example, carry out processing while holding a dummy wafer, and some process equipment need a wafer for cleaning reproduction at a specific frequency. By setting application groups in the load requests from these process equipment, the non product wafer required by each equipment can be carried at the required timing.

According to a seventh aspect, in the semiconductor production automating system of the sixth aspect, the host computer comprises a data application combination table memory which is registered by correlating at least one of the equipment, lot, conditions, and process, to a single key in order to link the product flow and the non product flow; a correlation table memory which correlation information comprising product lots is registered in when the data application combination table memory is checked at the timing when a product lot is processed in the correlated process and the conditions were defined; and a unit which links the product flow and the non product flow by additionally registering as non product lots of the correlation table memory the non product wafers which have been processed in the process equipment at frequency control timings.

Consequently, the host computer identifies non product wafers which were processed for the purpose of guaranteeing the product based on the flow and the application groups, and can link processing information such as the operation histories and measurements data of the non product wafers to the histories of the product lots. Therefore, the difficulty of tracking the histories is reduced.

An eighth aspect of this invention provides a computer-readable recording medium, used in a non product automating processing system comprising one or more process equipment relating to semiconductor production which are controlled by a host computer, the system automating the carrying of lots comprising product wafers including non product wafers set in a storage shelf to and from the process equipment and the process-tracking thereof. The recording medium stores a program which allows a computer to execute the steps of receiving a load request from the process equipment and checking whether batch formation is necessary; in the case where it has been determined that batch formation is not necessary, checking application group information which was output as an attachment, selecting a suitable lot in compliance with the group from the storage shelf, and issuing a carrying command to the automatic vehicle; checking by means of frequency control whether the lot in compliance with the group is at a required timing; when at a required timing, selecting a suitable lot specified by frequency control from the storage shelf and issuing a carrying command to the automatic vehicle; in the case where it has been determined that batch formation is necessary, consulting a master file and checking the application group, selecting a suitable lot in compliance with the group from the storage shelf and issuing a carrying command to the automatic vehicle; checking by means of frequency control whether the lot in compliance with the group is at a required timing; and, when at a required timing, extracting a suitable lot specified by frequency control from the storage shelf and issuing a carrying command to the automatic vehicle.

According to this invention, the applications of the NPWs are classified in detail with regard to carrying control, process tracking, and information management, and the classifications are held in the master file for each process of the NPW process flow. Therefore, it is possible to automate the operations of tracking the processes and carrying the NPWs which are required as the product lots pass along the line. The line can be completely automated with complete separation of products and human operators, thereby preventing generation of paticle caused by the human operators. Further, automating the operations of tracking the processes and carrying the NPWs makes it possible to control the flow of the NPWs along the line can in a single process. This eliminates the time which was wasted in the conventional method by the operator waiting for the required NPW timing, thereby improving the through-put of the system.

### BRIEF DESCRIPTION OF THE DRAWINGS

FIG. 1 is a block diagram showing the constitution of an automated processing system for non product wafer product of the present invention.

FIG. 2 is an operation concept diagram showing carrying-in and carrying-out states of a product carrier in a diffusion furnace.

FIG. 3 is an operation concept diagram showing carrying-in and carrying-out states of a product reference carrier in a diffusion furnace.

FIG. 4 is an operation concept diagram showing carrying-in and carrying-out states of a process check carrier in a diffusion furnace.

FIG. 5 is an operation concept diagram showing carrying-in and carrying-out states of an equipment pilot carrier in a diffusion furnace.

FIG. 6 is an operation concept diagram showing carrying-in and carrying-out states of an extra dummy carrier in a diffusion furnace.

FIG. 7 is an operation concept diagram showing carrying-in and carrying-out states of a side dummy carrier in a diffusion furnace.

FIG. 8 is a flowchart showing an operating sequence of a host computer.

FIG. 9 is a diagram showing the relationship between a product flow and an NPW flow in each process on a time axis.

### DESCRIPTION OF THE PREFERRED EMBODIMENTS

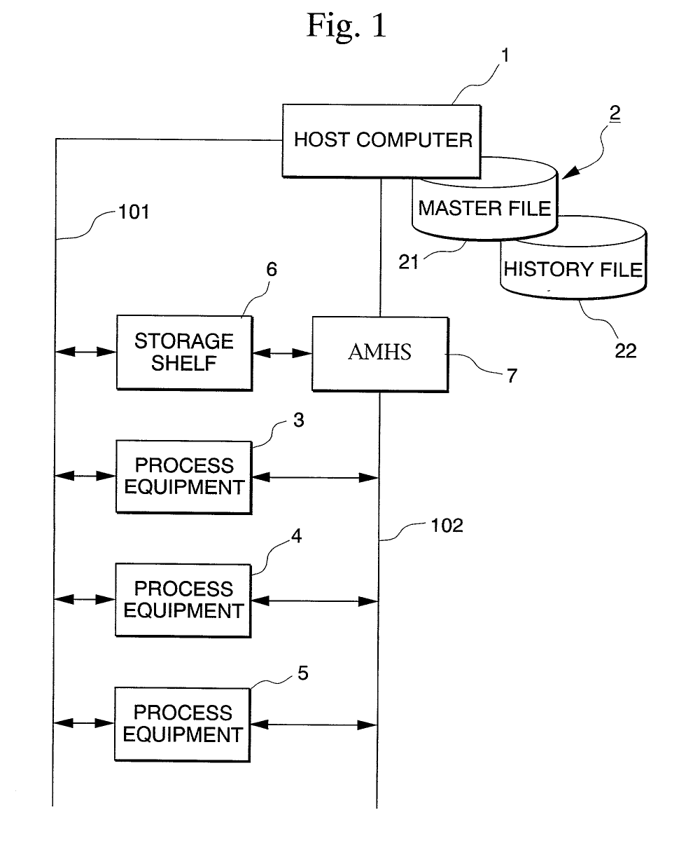

FIG. 1 is a diagram schematically showing the constitution of the automated processing system for non wafer product of this invention. In FIG. 1, reference numeral 1 represents a host computer having a large-capacity disk unit 2. A master file 21, a history file 22, and a great number of data files such as files of process data, measuring data and the like, which are explained later, are allocated and stored in the large-capacity disk unit 2. The data in these files is read and processed by the host computer 1 whenever required.

Reference numerals 3, 4, and 5 represent various types of processing equipment for semiconductor manufacture, e.g. a diffusion furnace, an etching equipment, a measuring equipment, etc. These processing equipment are connected to the host computer 1 via a communications line 101. Reference numeral 6 represents a in-process shelf for product wafers including non product wafers. The product wafers including NPWs which are set in this in-process shelf 6 are carried in and out along the carrier track 102 in compliance with the host computer 1 or the processing equipment 3, 4, and 5. Reference numeral 7 represents an automatic material handling system (AHMS) which delivers the product lots set in the in-process shelf 6 to the processing equipment 3 to 5 in compliance with the host computer 1.

In the constitution described above, automatic material handling during the process is controlled in the following way. The processing equipment 3 (4, 5) sends load request to the host computer 1. The host computer 1 is triggered by this request, and dispatches the lot which is being stored on the in-process shelf to the equipment which made the request, and sends a command to carry the lot to the AMHS 7. Some processing equipment 3 (4, 5) execute processing while holding a dummy wafer, and some equipment require a wafer for insitu cleaning at specified frequency. By setting “application groups” as information in the load request from the processing equipment 3 (4, 5), the NPWs required by the processing equipment 3 (4, 5) can be carried at the required time.

Furthermore, the host computer controls the frequency of non product wafers which are required in regular processing for guaranteeing the product or controlling the process equipment, and sends commands to carry the NPWs held in the in-process shelf at the required timing.

Table 2 is a diagram showing the constitution of a master file which is defined by a user and created by the host computer 1. To automate the NPWs, the application of each NPW is entered in the master file 21 which defines the NPW process flow and processing conditions, thereby enabling the carrying and information to be controlled in accordance with each individual application. In addition, by appending the application information to the load requests sent from the processing equipment, the NPWs having the required applications can be automatically carried at timings which can only be determined by the processing equipment.

TABLE 2

| NPW NAME A: | | | |
|---|---|---|---|
| APPLICATION GROUP(E) | | PRODUCT NAME B: PRODUCT (H) | |
| PROCESS 1 | RECIPE 1 (N) | PROCESS 1 | RECIPE 1 (H) |
| PROCESS 2 | RECIPE 2 (N) | PROCESS 2 | RECIPE 2 (H) |
| PROCESS 3 | RECIPE 3 (N) | PROCESS 3 | RECIPE 3 (H) |
| PROCESS 4 | RECIPE 4 (E) | PROCESS 4 | RECIPE 4 (H) |
| PROCESS 5 | RECIPE 5 (N) | PROCESS 5 | RECIPE 5 (H) |
| PROCESS 6 | RECIPE 6 (N) | PROCESS 6 | RECIPE 6 (H) |

Specifically, the host computer 1 holds flags as “application groups” in which the purpose of the NPW is appended to the NPW name. Similarly, the host computer 1 holds “application groups” for the uniquely determined process flow (processing conditions) for each NPW name. The non product wafer automating system shown in FIG. 1 controls carrying and information by using application groups which are set during in-processing. The relationship between the two is as follows. The “application group” of each process flow becomes upper, and the “application group” of each NPW name is used as a substitute only when there is no specification for each process flow. The “application groups” are created in accordance with the applications of the NPWs. Furthermore, an application group identifying the product is appended to the product name.

Table 3 shows an example of NPW application groups. This example shows eleven application groups comprising product H, system test item T, standard sample G, reference withdraw R, reference supply F, process check M, equipment pilot P, reproduced and surface prepared wafer N, dummy D, extra dummy E, and side dummy S.

TABLE 3

| | |
|---|---|
| REFERENCE WITHDRAW | R |
| REFERENCE SUPPLY | F |
| PROCESS CHECK | M |
| EQUIPMENT PILOT | P |
| REPRODUCED AND SURFACE PREPARED WAFER | N |
| DUMMY | D |
| EXTRA DUMMY | E |
| SIDE DUMMY | S |
| PRODUCT | H |
| SYSTEM TEST ITEM | T |
| STANDARD SAMPLE | G |

When the process equipment 3 (4, 5) comprises a diffusion furnace, side dummy S, reference withdraw R or process check M, and extra dummy E are used as the application groups. The side dummy S and the extra dummy E are provided permanently inside the equipment, and the frequency of their use is internally managed. When the limit is reached, the equipment ejects the dummy and sends a request for a new dummy to the host computer 1. The host computer 1 determines the dummy type based on an in-process conditions key and the application group, and the AMHS 7 automatically supplies the requested dummy. The products are processed in a batch of several lots, and references withdraw R or process check M are inserted into the batch and processed in the same manner as the products. The equipment pilot P for controlling the state of the equipment is not processed at the same time as the products.

The host computer 1 changes the batch combination in accordance with the purpose of the check. The process equipment 3 (4, 5) changes the position of the wafer inside the furnace in accordance with the constitution of the application groups combined in the batch. The measurement of the wafer, obtained in the next process by using the reference withdraw R or process check M, is used as batched product data in linkage with the master file 21 of the host computer 1. The linkage method will be explained later.

There are various types of dummy such as running dummy, process dummy, and cleaning dummy. The running dummy is used to stabilize the equipment at start-up after maintenance and the like. Consequently, the running dummy is usually supplied when needed from an automatic shelf. The process dummy is processed immediately before processing the product wafer in order to stabilize processing conditions. The process dummy is provided permanently inside the equipment, and is used whenever needed (e.g. when the conditions of the equipment change, during gaps between processing, etc.) before processing the product wafer. When a permanently provided dummy has been used, it is automatically replaced by one from the automated shelf. The cleaning dummy is used for cleaning the inside of the equipment. Depending on the structure of the equipment and the frequency of the cleaning, the cleaning dummy may be provided permanently inside the equipment or supplied from the automated shelf when needed.

Since the AMHS 7 and the interface are jointly used with the product, they send load requests between the process equipment 3 (4, 5) and the host computer 1 by using application groups, receive the result (application group) of operation inquiries from the host computer 1, and determine whether to process the product or insert a dummy at a predetermined position.

Subsequently, examples of the use of application groups in various types of process equipment will be explained in detail. Since application groups can be used in various ways depending on the combinations, some but not all of the eleven application groups shown in Table 3 can be unarchived. Even when the process equipment is the same, the application group to be used differs depending upon the type of equipment. In this example, H, N, D, T, F, R, M, P, E, and S are used as the application groups for a diffusion furnace; H, N, D, T, M, P, and E are used as the application groups for one type of sputtering equipment or a dry etching equipment; H, N, D, T, and P are used as the application groups for another type of sputtering equipment or a dry etching equipment; and H, N, T, and G are used as the application groups for a measuring equipment.

The host computer 1 controls the application group which each lot belongs to during the actual process. Therefore, each lot receives an application group from the host computer 1 at a timing which each lot is set by the process equipment 3 (4, 5). After the application group information has been received, the contents of operations and information control of the process equipment 3 (4, 5) are changed in accordance with the application group.

The NPW carrying timings of the process equipment 3 (4, 5) such as a diffusion furnace are controlled by the process equipment 3 (4, 5) itself. Consequently, the application group of the required NPW is transmitted to the host computer 1 at the required timing. The host computer 1 receives the load request of the application group, and transmits a command to carry the NPW to the process equipment 3 (4, 5) to the AMHS 7. After the NPW has been carried to the process equipment 3 (4, 5), the process equipment 3 (4, 5) receives (reconfirms) the application group from the host computer 1 and operates in compliance with the application group.

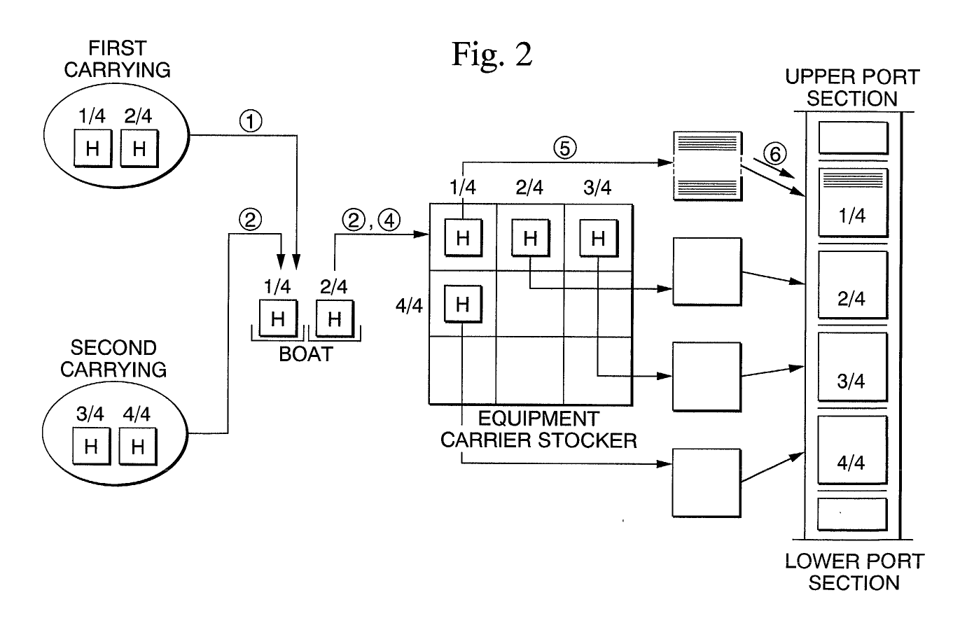

FIGS. 2 to 7 show examples of uses of application groups in the case where the process equipment 3 (4, 5) comprises a diffusion furnace. FIGS. 2 to 7 show product lots comprising NPWs being carried in and out of the diffusion furnace.

In FIG. 2, the product carrier (H) identifies lots 1 to N as one batch. After batch formation processing by the host computer 1, 1 to N product lots are identified as one batch and processed simultaneously.

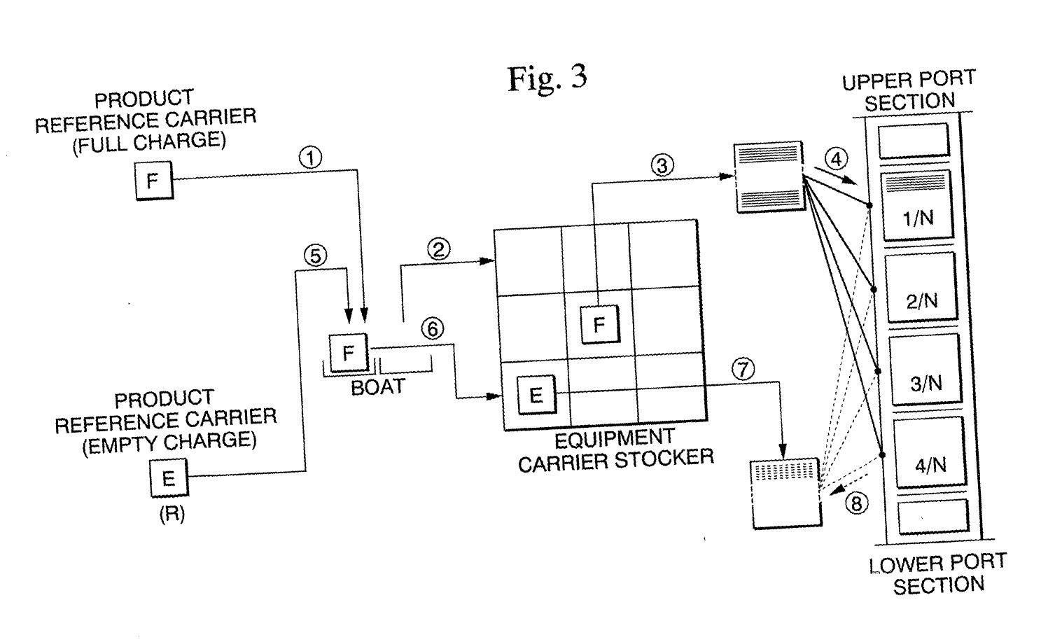

In FIG. 3, there are two types of product reference carrier: a carrier for reference wafer supply (F) and a carrier for recovering (R). The product reference supply carriers are requested by the diffusion equipment out of synchronism with the load request for the product carrier, and stocked inside the equipment ((1) to (2)). The diffusion equipment supplies the reference wafers from the carrier whenever necessary ((3) to (4)). When the carrier F for reference wafer supply is empty, the diffusion equipment automatically discharges the carrier.

The carrier for product reference withdraw is carried at the same time as the product carrier. When the equipment transmits a load request for a product carrier H, the host computer 1 executes batch formation processing of the lot to be processed. The host computer 1 determines whether to carry out a product reference and, when inserting a product reference, transmits a host command to the equipment. The carrier for product reference recovery is carried together with the product carrier ((5) to (6)). After the product has been processed, the diffusion equipment withdraw the reference wafer which was processed in the same way as the product in the withdraw carrier (empty carrier) ((7) to (8)). The operation of withdrawing the product withdraw carrier performed by the diffusion equipment is given priority over the product carrier H.

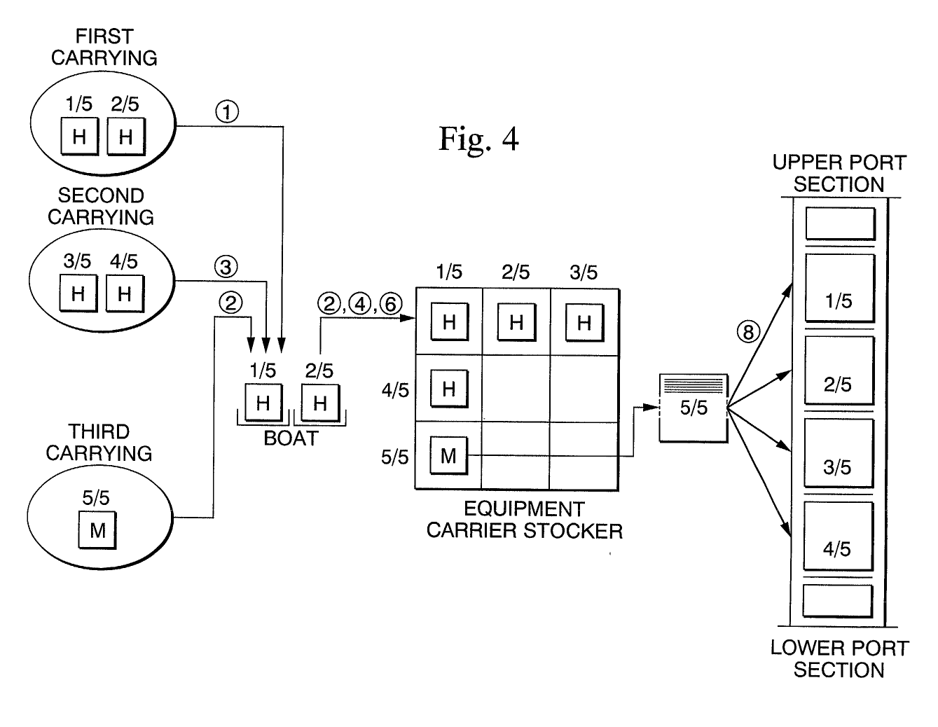

In FIG. 4, the process check comprises a monitor wafer which is processed at the same time as the product. The process check wafers are not stocked inside the equipment like the product references, but are supplied from the outside. The process check carrier contains a monitor wafer M. When the equipment transmits a load request for a product carrier H, the host computer 1 forms a batch of the lot to be processed. The host computer 1 determines whether to carry in a process check. When a process check is to be inserted, the process check carrier is carried together with the product carrier H ((5)). The diffusion equipment processes the process check M at the same time as the product, and the monitor wafer is supplied to a monitor slot of the boat ((7) and (8)). In the diffusion equipment, the process check wafer is returned to its original carrier after processing has ended.

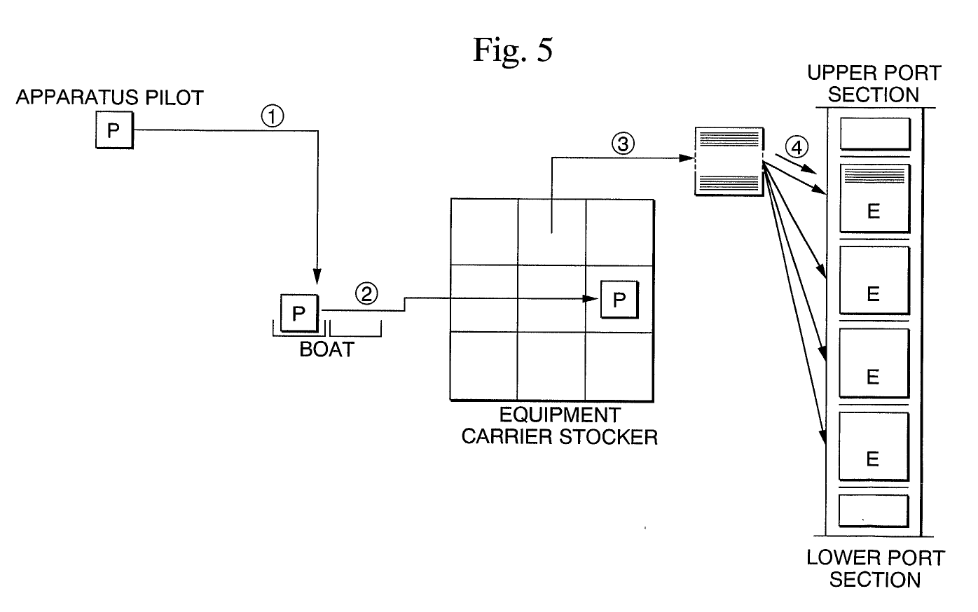

The equipment pilot carrier is used in checking conditions after equipment maintenance, and the like. In FIG. 5, when the equipment has sent a load request for the product carrier to the host computer 1, the host computer 1 determines that the equipment pilot should be substituted as the product. The equipment pilot P carries in one carrier unit ((1)). The diffusion equipment processes the equipment pilot P in the monitor slot, executing processing which is different to that of the product by inserting an extra dummy instead. After the equipment pilot has been processed, it is discharged in one carrier unit.

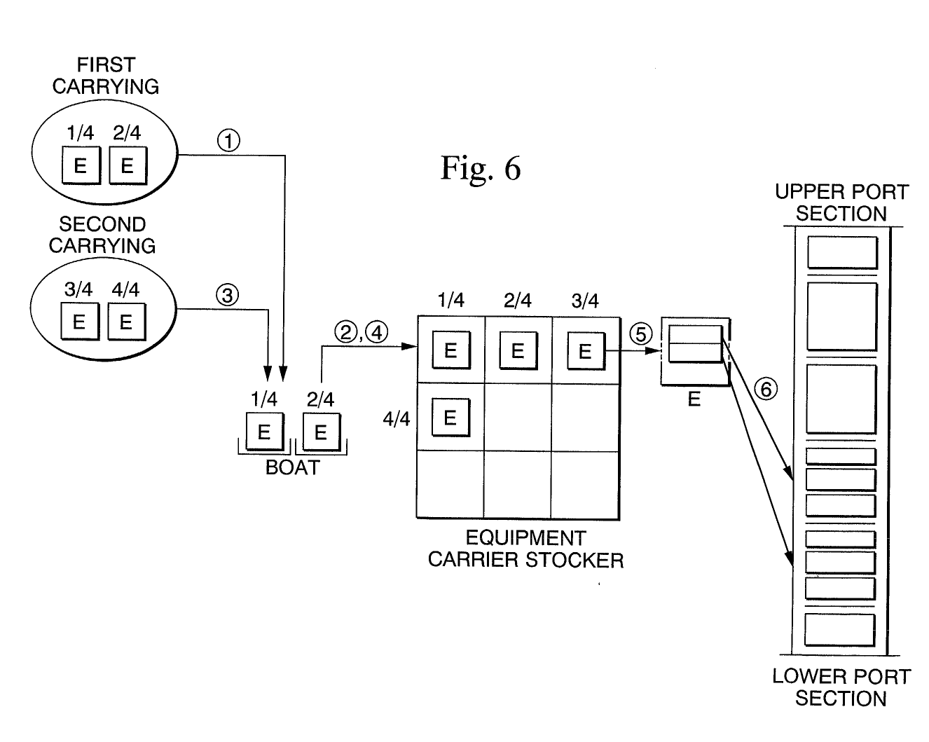

The extra dummy E represents a wafer for supplementing missing product wafers at the boat. In FIG. 6, the diffusion equipment sends a load request when there is no extra dummy in the equipment or when the prescribed number of dummies has not been met ((1) to (2)). When the number of times that an extra dummy E has been used in the diffusion equipment (in the equipment carrier stocker) has exceeded a permissible number, it is discharged (replaced).

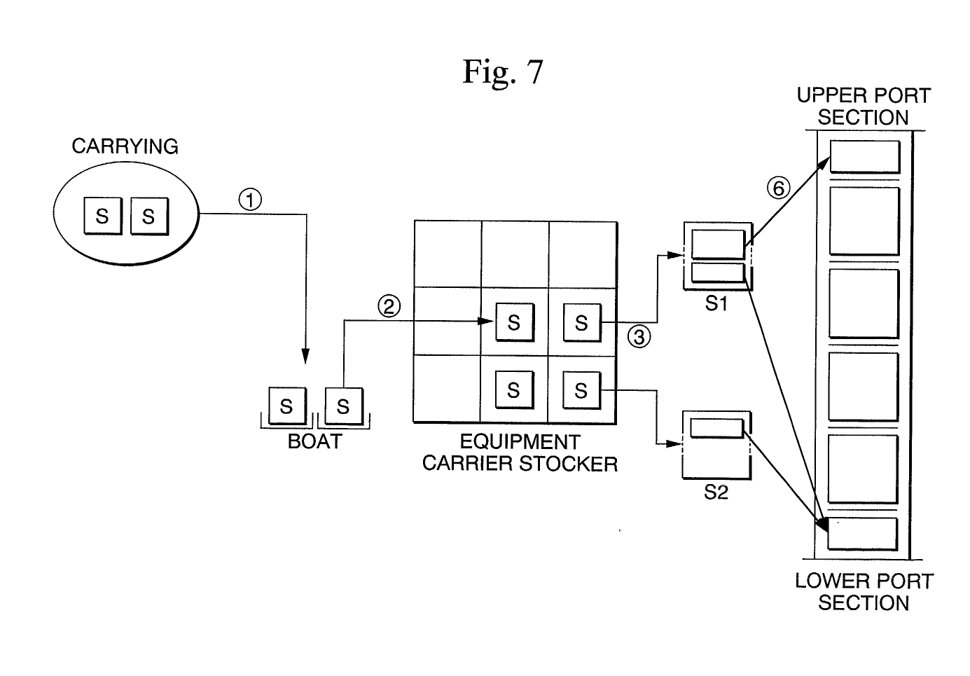

The side dummy S represents a dummy which is permanently provided at the boat. In FIG. 7, the diffusion equipment transmits a load request when there is no side dummy in the equipment or when the prescribed number of dummies has not been met ((1) to (2)). When the number of times that a side dummy has been used in the boat of the diffusion equipment (number of processed batches) exceeds a permissible number, a side dummy which is stocked inside the equipment (in the equipment carrier stocker) is supplied ((3) to (4)). The dummy which has exceeded its permissible number of uses is returned to the carrier and discharged from the equipment. The side dummy carrier transmits a load request when there is no side dummy in the equipment or when the prescribed number of dummies has not been met ((1) to (2)).

In the diffusion furnace, the application groups N, D, and T, are handled in the same way as the product (H). When H, N, D, T, M, and P have been set as the application groups in one type of sputtering equipment or a dry etching equipment, the operation is the same as the diffusion furnace mentioned above. The extra dummy E is held inside the equipment in the same manner as shown in FIG. 6, and is used when necessary. However, the extra dummy E is used in stabilizing the equipment and not in supplementing a defective product wafer. When an extra dummy has been used beyond its limit, it is discharged (replaced) in the same way as shown in FIG. 6. Moreover, when H, N, D, T, M, and P have been set in another type of sputtering equipment or dry etching equipment, the operation is the same as the diffusion furnace. When H, N, T, and G have been set in the measurement equipment, the operation is the same as the diffusion furnace.

When processing lots of application groups, the operating status of the process equipment 3 (4, 5) changes. The operating status is an important parameter in managing the production line and is essential for understanding line capability. Table 4 shows the treatment of the application groups (i.e. how the operating status is changed) in a general process equipment. As is clear form Table 4, at the start of processing, the preparatory status notified to the host computer 1 differs according to the lot type (product, product reference, process check, equipment pilot, dummy, standard sample, reproduced item). The lot types are determined by application groups contained in a response from the host computer 1 to an inquiry.

TABLE 4

| | | | APPLI- |
|---|---|---|---|
| | | | CATION |
| LOT TYPE: | APPLICATION: | STATUS: | GROUP: |
| PRODUCT | — | IN-OPERATION | H |
| PRODUCT | MONITOR WAFER IN | NOT UNDER | F, R |
| REFERENCE | AN LPCVD FURNACE | OPERATION | |
| (SUPPLY, | AND DIFFUSION | CONTROL | |
| RECOVERY) | FURNACE | | |
| PROCESS | LOT USED FOR | PREPARATION | M |
| CHECK | REGULARLY CHECK- | | |
| | ING THE STATUS OF | | |
| | PRODUCTS AND | | |
| | EQUIPMENT | | |
| EQUIPMENT | EQUIPMENT INSPEC- | PREPARATION | P |
| PILOT | TION LOT AT START- | | |
| | UP AND AFTER | | |
| | MAINTENANCE | | |
| DUMMY | LOT FOR SUPPLE- | NOT UNDER | E, S |
| | MENTING WHEN | OPERATION | |
| | NUMBER OF WAFERS | CONTROL | |
| | DOES NOT MEET | | |
| | STIPULATED VALUE | | |
| STANDARD | LOT USED IN CHECK- | PREPARATION | G |
| SAMPLE | ING PRECISION OF | | |
| | MEASUREMENT | | |
| | EQUIPMENT | | |
| REPRO- | ALL NON PRODUCTS | IN-OPERATION | N |
| DUCTION | REPRODUCED | | |
| | WITHIN THE FAB | | |
| TEST ITEM | HYPOTHETICAL LOT | IN-OPERATION | T |
| | USED IN CHECKING | | |
| | VARIOUS SYSTEMS | | |

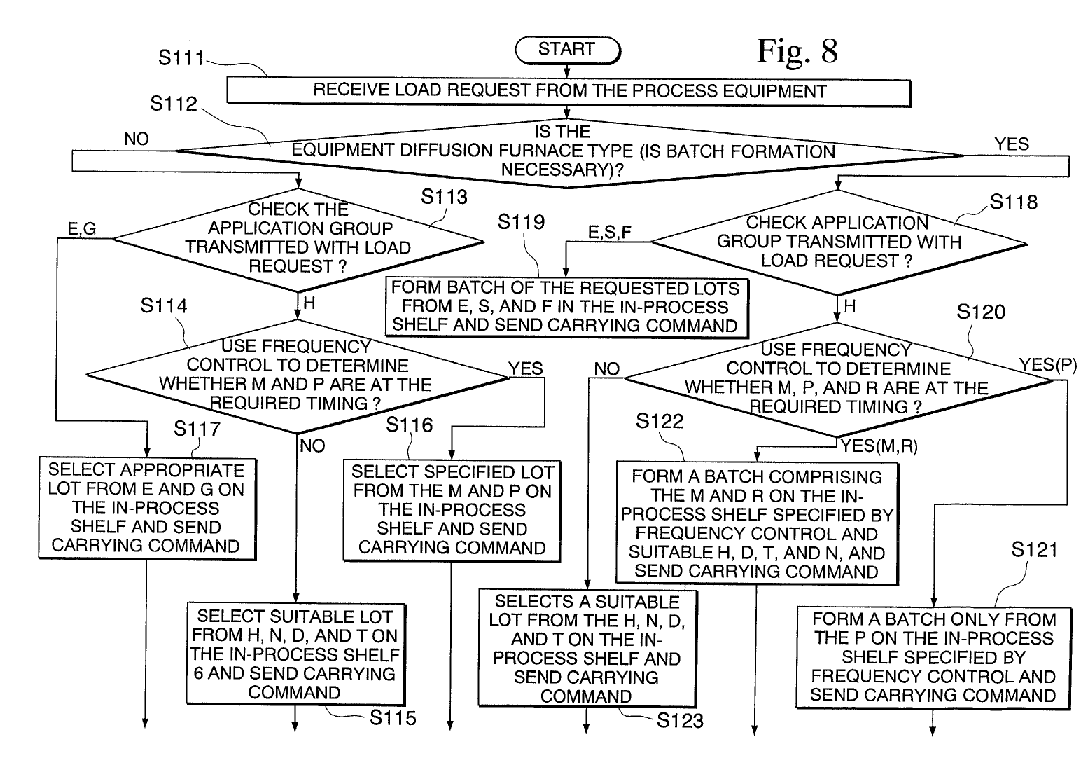

FIG. 8 is a diagram showing a flowchart of the flow of processing when the host computer 1 has received a load request from the process equipment 3 (4, 5). Firstly, the host computer 1 receives the load request from the process equipment 3 (4, 5) (step Sill) and checks the equipment type (step S112). In this example, when the process equipment 3 (4, 5) which made the request is not a diffusion furnace, that is, when batch formation is not necessary, the host computer 1 checks the application group which was transmitted at the same time as the request (step S113). When the application group is extra dummy E or standard sample G, the host computer 1 selects the appropriate lot from the E and G on the in-process shelf 6 and sends a carrying command to the AMHS 7 (step S117). When the application group was product H, the host computer 1 uses frequency control to determine whether the process check M and the equipment pilot P are at the required timing (step S114). When the process check M and the equipment pilot P are at the required timing, the host computer 1 sends a command to the AMHS 7 to carry the specified lot from the M and P on the in-process shelf 6 (step S116). When the process check M and the equipment pilot P are not at the required timing, the host computer 1 selects a suitable lot from the H, N, D, and T on the in-process shelf 6 (step S115) and sends a command to the AMHS 7 to carry the selected lot.

On the other hand, when it has been confirmed in step S112 that the process equipment is a diffusion furnace type, the host computer 1 checks the application group which was transmitted at the same time as the load request (step S118). When the application group is one of extra dummy E, side dummy S, and reference supply F, the host computer 1 forms a batch of the requested lots from the E, S, and F in the in-process shelf 6, and sends a carrying command to the AMHS 7 (step S119). When the application group was product H, the host computer 1 uses frequency control to determine whether the process check M, the equipment pilot P, and the reference withdraw R are at the required timing (step S120). When M, P, and R are at the required timing, the host computer 1 forms a batch only from the P on the in-process shelf 6 and sends a command to the AMHS 7 to carry it (step S121). When the process check M and the reference withdraw R are at the required timing, the host computer 1 forms a batch comprising the M and R on the in-process shelf 6 which were specified by frequency control and suitable H, D, T, and N, and sends a carrying command to the AMHS 7 (step S122).

When it is determined in step S120 that M, P, and R are not at the required timing, the host computer 1 selects a suitable lot from the H, N, D, and T on the in-process shelf 6 and sends a carrying command to the AMHS 7 (step S123).

The host computer 1 controls frequency at all times by using conditions such as the processed lots or time elapsed since the previous check, and unit codes, and monitors at a predetermined timing. Alternatively, the host computer 1 measures the timings based on the state of the process equipment and the result of processed lots.

Moreover, the host computer 1 identifies an NPW which was processed for the purpose of guaranteeing the product based on its flow (recipe) and application group, and links the operation history, measurement data, and the like of the NPW to the history of the product lot. To control the state of the equipment, the host computer 1 determines the purpose of the processed NPW based on its application group and changes the equipment status. As shown in Table 4, equipment statuses comprise “operating”, “preparing”, “under maintenance”, etc.

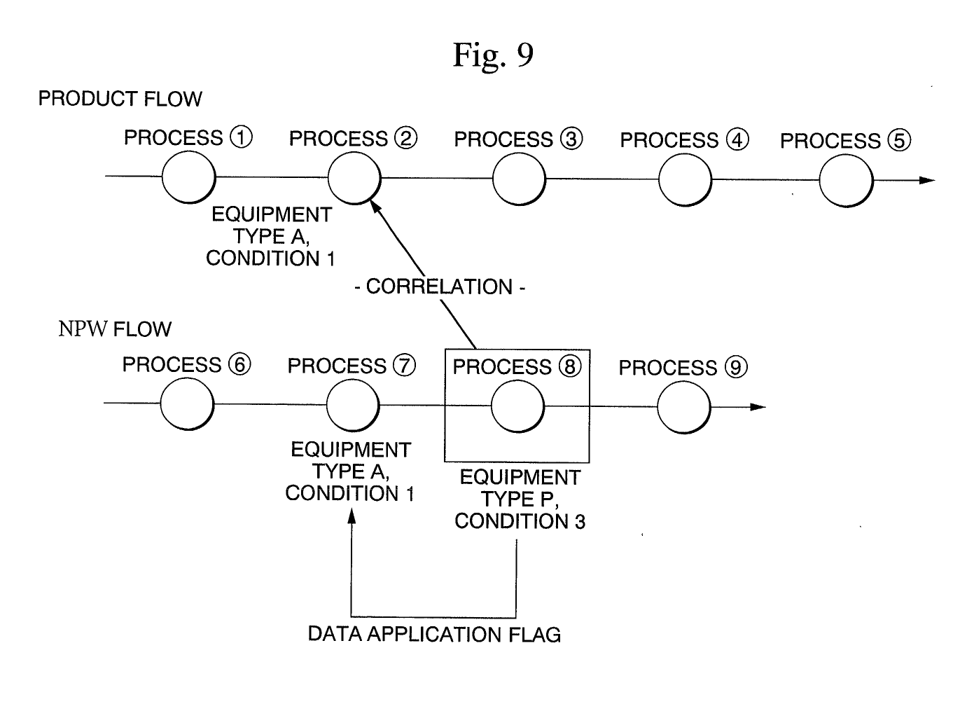

A method for correlating the histories of the product and the NPW will be explained while referring to the process flow shown in FIG. 9, the data application combination table shown in Table 5, and the correlation table shown in Tables 6 to 8.

TABLE 5
DATA APPLICATION COMBINATION TABLE

EQUIPMENT TYPE A-CONDITION 1-EQUIPMENT TYPE B-
CONDITION 3
EQUIPMENT TYPE A-CONDITION 2-EQUIPMENT TYPE C-
CONDITION 4

TABLE 6
EQUIPMENT TYPE A, UNIT CODE #001

| APPLI- | | | | |
|---|---|---|---|---|
| CATION | | | APPLICATION | |
| SOURCE | NPW | PRODUCT | DESTINATION | RELATED |
| CONDITION | LOT | LOT | PROCESS | CONDITIONS |
| EQUIPMENT | | PRODUCT | PROCESS 2 | EQUIPMENT |
| TYPE B | | LOT 1 | | TYPE A |
| CONDITION 3 | | | | CONDITION 1 |

TABLE 7
EQUIPMENT TYPE A, UNIT CODE #001

| APPLI- | | | | |
|---|---|---|---|---|
| CATION | | | APPLICATION | |
| SOURCE | NPW | PRODUCT | DESTINATION | RELATED |
| CONDITION | LOT | LOT | PROCESS | CONDITIONS |
| EQUIPMENT | | PRODUCT | PROCESS 2 | EQUIPMENT |
| TYPE B | | LOT 1 | | TYPE A |
| CONDITION 3 | | | | CONDITION 1 |
| EQUIPMENT | | PRODUCT | PROCESS 10 | EQUIPMENT |
| TYPE C | | LOT 2 | | TYPE A |
| CONDITION 4 | | | | CONDITION 2 |
| EQUIPMENT | | PRODUCT | PROCESS 2 | EQUIPMENT |
| TYPE B | | LOT 3 | | TYPE A |
| CONDITION 3 | | | | CONDITION 1 |

TABLE 8
EQUIPMENT TYPE A, UNIT CODE #001

| APPLI- | | | | |
|---|---|---|---|---|
| CATION | | | APPLICATION | |
| SOURCE | NPW | PRODUCT | DESTINATION | RELATED |
| CONDITION | LOT | LOT | PROCESS | CONDITIONS |
| EQUIPMENT | NAP | PRODUCT | PROCESS 2 | EQUIPMENT |
| TYPE B | LOT | LOT 1 | | TYPE A |
| CONDITION 3 | 7 | | | CONDITION 1 |
| EQUIPMENT | | PRODUCT | PROCESS 10 | EQUIPMENT |
| TYPE C | | LOT 2 | | TYPE A |
| CONDITION 4 | | | | CONDITION 2 |
| EQUIPMENT | NAP | PRODUCT | PROCESS 2 | EQUIPMENT |
| TYPE B | LOT | LOT 3 | | TYPE A |
| CONDITION 3 | 7 | | | CONDITION 1 |

FIG. 9 shows the product flow and the NPW flow in each process. The host computer 1 checks the data application combination table at the timing when the product lot 1 is processed in process (2) and, when the condition (equipment type A condition 1) is registered, stores it in the correlation table. The correlation table comprises the equipment types and each unit code. Since the first correlated NPW lot has not been determined, the NPW lot box is empty (Table 6). The product lots are stored in the correlation table (Table 7) as they are processed. At the frequency control timing, when the NPW has been processed by equipment type A unit code #001, a lot name in compliance with the contents defined in the data application combination table is added to the corresponding NPW lot box in the correlation table, thereby completing the correlation record (Table 8). The host computer 1 refers to the correlation record when application the data.

In a diffusion furnace, the batched products and the corresponding NPW are processed simultaneously. Therefore, the correlation record of the correlation table is completed when the batch is processed.

As described above, in this invention, the host computer receives a load request from the process equipment and, triggered by this request, dispatches a lot held on a in-process shelf to the equipment and sends a command to carry the lot to an automated vehicle. Some process equipment, for example, process while holding a dummy wafer, and some process equipment need a wafer for cleaning reproduction at a specific frequency. By setting application groups in the load requests from these process equipment, the non product wafer required by each equipment can be carried at the required timing. The host computer identifies non product wafers which were processed for the purpose of guaranteeing the product based on the application groups, and can link processing information such as the operation histories and measurements of the non product wafers to the histories of the product lots. As a consequence, the difficulty of tracking the histories can be reduced.

In FIG. 1, a program for realizing the functions of the host computer 1 may be recorded in a computer-readable recording medium, so that the program can be read and executed by other computer systems. Here, “computer system” includes hardware such as peripheral unit and OS.

The computer-readable recording medium may comprise a portable medium such as a floppy disk, an optical magnetic disk, a ROM, and a CD-ROM, or a memory equipment such as a hard disk provided in the computer system. Moreover, the computer-readable recording medium may be one which holds fixed-time programs such as a volatile memory (RAM) in computer systems which function as a server and a client when transmitting programs via a network, such as the internet, or a communications line, such as a telephone line. The program may be transmitted from a computer system, in which the program is stored in a memory equipment or the like, via a transmission medium or by waves transmitted in the transmission medium to another computer system. The transmission medium which transmits the program comprises a medium capable of transmitting information e.g. a network (communications net) such as the internet and a communications line such as a telephone line.

The program may be one for realizing some of the functions mentioned above. Furthermore, the program may comprise what is termed a differential file (differential program), whereby the functions are realized in combination with programs already stored in the computer system.

According to the present invention described above, application groups for clarifying the controlling and managing methods in each process of an NPW process flow are held in a master file. Data are applied to the product history and the equipment status is changed based on the application group of the processed lot. In addition, frequency is controlled. By these means, commands to carry NPWs can be issued regularly. Furthermore, the process equipment can control its own status, and can send a load request for the NPW required at start-up at the required timing.

The applications of the NPWs are classified in detail with regard to carrying control, process tracking, and information management, and the classifications are held in the master file for each process of the NPW process flow. Therefore, it is possible to automate the operations of tracking the processes and carrying NPWs which are required as the product lots pass along the line. As a result, the line can be completely automated with complete separation of products and human operators, thereby preventing the generation of particle coased by human operators. Further, automating the operations of tracking the processes and carrying the NPWs makes it possible to control the flow of the NPWs along the line can in a single process. This eliminates the time which was wasted in the conventional method by the operator waiting for the required NPW timing, thereby improving the through-put of the system and increasing the precision of the equipment operating information.

What is claimed is:

1. A method for automating product wafers and non product wafer in an automated semiconductor production system, in which one or more process equipment relating to semiconductor production are controlled by a host computer, and carrying and process tracking of product wafers including non product wafers are automated, the method comprising the steps of:
appending application groups, which are classified according to purpose and operation in the respective processes, by a host computer as information in a master file which the flow of said processes and conditions for processing in each of said processes are stored; and
providing processing conditions comprising application groups which are stored in a master file in accordance with load requests for said product wafer and non product wafer generated by said equipmentes, whereby said product wafer and non product wafer can be carried in accordance with their individual application groups and process tracking can be controlled.

2. The automated processing method for non product wafer as described in claim 1, wherein said host computer determines a non product wafer to be processed by said process equipment based on the process flow and application group, and correlates the processing history of the product lot with the processing history of said non product wafer, and links at least one of said equipment type, lot number, processing conditions, and process, to a single key.

3. The automated processing method for non product wafer as described in claim 1, wherein said host computer determines the purpose of each type of product lot and non product lot based on application groups contained in inquiry responses from said process equipment, and updates the status of the equipment.

4. The automated processing method for non product wafer as described in claim 1, wherein, with regard to a non product wafer which requires regular processing, said host computer individually controls at least one of (i) time elapsed since the previous check and (ii) the number of processed lots in accordance with processing conditions, and issues a carrying command for said non product wafer after counting a predetermined time or the number of processed lots.

5. The automated processing method for non product wafer as described in claim 1, wherein said process equipment supplies and withdraws non product wafers in accordance with application groups obtained from inquiry responses to said host computer, or combinations of batched application groups.

6. A semiconductor production automating system for automating the carrying and process-tracking of product wafers including non product wafers, one or more process equipment being controlled by a host computer, the system comprising:
a storage shelf which stores said product wafers comprising non product wafers in lot units;
an automatic material handling system which carries said product wafers comprising non product wafers to and from said storage shelf and said process equipment in compliance with carrying commands issued by said host computer;
said host computer appending application groups, which are classified according to purpose and operation in the respective processes, as information in a master file which the flow of said processes and conditions for processing in each of said processes are stored, and providing processing conditions comprising application groups which are stored in said master file in accordance with load requests for said product wafers and non product wafers generated by said equipment.

7. The semiconductor production automating system as described in claim 6, said host computer comprising
a data application combination table memory which is registered by correlating at least one of said equipment, lot, conditions, and process, to a single key in order to link the product flow and the non product flow;
a correlation table memory which correlation information comprising product lots is registered in when said data application combination table memory is checked at the timing when a product lot is processed in said correlated process and the conditions were defined; and
a unit which links the product flow and the non product flow by additionally registering as non product lots of the correlation table memory said non product wafers which have been processed in said process equipment at frequency control timings.

8. A computer-readable recording medium, used in a non product automating processing system comprising one or more process equipment relating to semiconductor production which are controlled by a host computer, the system automating the carrying of lots comprising product wafers including non product wafers set in a storage shelf to and from said process equipment and the process-tracking thereof, the recording medium storing a program which allows a computer to execute the steps of:
receiving a load request from said process equipment and checking whether batch formation is necessary;
in the case where it has been determined that batch formation is not necessary, checking application group information which was output as an attachment, selecting a suitable lot in compliance with the group from said storage shelf, and issuing a carrying command to said automatic vehicle;
checking by means of frequency control whether the lot in compliance with the group is at a required timing;
when at a required timing, selecting a suitable lot specified by frequency control from said storage shelf and issuing a carrying command to said automatic vehicle;
in the case where it has been determined that batch formation is necessary, consulting a master file and checking the application group, selecting a suitable lot in compliance with the group from said storage shelf and issuing a carrying command to said automatic vehicle;
checking by means of frequency control whether the lot in compliance with the group is at a required timing; and
when at a required timing, extracting a suitable lot specified by frequency control from said storage shelf and issuing a carrying command to said automatic vehicle.
